(19) United States
(12) Patent Application Publication
(10) Pub. No.: US 2024/0377760 A1
(43) Pub. Date: Nov. 14, 2024

(54) PHOTOLITHOGRAPHY APPARATUS AND OPERATION METHOD OF THE SAME

(71) Applicant: SAMSUNG ELECTRONICS CO., LTD., Suwon-si (KR)

(72) Inventors: Hyunwoong HWANG, Suwon-si (KR); Yongsuk CHOI, Suwon-si (KR); Yonghoon HWANG, Suwon-si (KR); Kyung-Won KANG, Suwon-si (KR); Dong-Wook KIM, Suwon-si (KR); Seok HEO, Suwon-si (KR)

(21) Appl. No.: 18/505,041

(22) Filed: Nov. 8, 2023

(30) Foreign Application Priority Data
May 8, 2023 (KR) 10-2023-0059257

(51) Int. Cl. G03F 7/00

(52) U.S. Cl. CPC G03F 7/706845; G03F 7/70625; H01L 21/027

(57) ABSTRACT

A photolithography apparatus according to an embodiment includes an exposure portion performing an exposure process, a plurality of track portions each performing a coating process and a developing process, and an interface portion connecting the exposure portion and the plurality of track portions to transfer a substrate on which a photolithography process is performed between the exposure portion and the plurality of track portions.

### CROSS-REFERENCE TO RELATED APPLICATION

This application claims priority to and the benefit of Korean Patent Application No. 10-2023-0059257 filed in the Korean Intellectual Property Office on May 8, 2023, the disclosure of which is incorporated herein by reference in its entirety.

### BACKGROUND

### (a) Field

The present disclosure relates to a photolithography apparatus and an operation method of the same.

### (b) Description of the Related Art

A semiconductor device may be manufactured by repeating a process of forming a layer having a predetermined pattern on a wafer. Unit processes such as deposition process, photolithography process, and etching process may be performed to form the layer with the predetermined pattern.

The photolithography process may include a coating process for forming a photoresist layer, a soft bake process, an exposure process, a post exposure bake (PEB) process, a developing process, a hard bake process, and the like.

In the photolithography process, if a delay time (e.g., a post-exposure delay time (PED) between the exposure process and the post-exposure bake process) becomes longer, qualities of a semiconductor device may deteriorate. For example, critical dimension (CD) may be changed. Accordingly, to manage the delay time, an in-line type photolithography apparatus in which the photolithography process sequentially proceeds has been proposed.

The in-line type photography apparatus includes one exposure portion for performing an exposure process and one track portion for performing a coating process, a developing process, and the like. Thus, the in-line type photolithography apparatus may have limitations in improving productivity of a photolithography process. That is, in order to improve productivity, an operation rate of an expensive exposure portion should by maximized. However, the operation rate of the exposure portion may be directly affected and be lowered by a state of the track portion.

### SUMMARY

Embodiments may provide a photolithography apparatus and an operation method of the same that may improve productivity and quality of the semiconductor device.

A photolithography apparatus according to an embodiment includes an exposure portion configured to perform an exposure process on a substrate, a plurality of track portions, each of the plurality of track portions configured to perform a coating process and a developing process on the substrate, and an interface portion connecting the exposure portion and the plurality of track portions, wherein the interface portion is configured to transfer the substrate between the exposure portion and the plurality of track portions.

An operation method of a photolithography apparatus according to an embodiment includes forming a photoresist layer on each of a plurality of substrates, forming an exposed photoresist layer on the plurality of substrates, and performing a developing process on the plurality of substrates. The photoresist layer is formed on the plurality of substrates in a plurality of track portions, respectively. The plurality of substrates are transferred to an exposure portion and an exposure process is performed in the exposure portion to form the exposed photoresist layer on each of the plurality of substrates. The plurality of substrates are transferred to the plurality of track portions and the developing process is performed on the exposed photoresist layer on each of the plurality of substrates in the plurality of tack portions.

An operation method of a photolithography apparatus according to an embodiment relates to an operation method of a photolithography apparatus including an exposure portion, a plurality of track portions, and an interface portion. The method includes periodically detecting whether any of the plurality of track portions are operating abnormally while operating the plurality of track portions simultaneously, either in a fully operational state or a partial operational state. In response to detecting that one of the plurality of track portions is operating abnormally, the method includes stopping the one of the plurality of track portions that is operating abnormally and selectively operating remaining ones of the plurality of track portions.

According to the embodiment, the productivity of the photolithography process and the quality of the semiconductor device may be improved by minimizing stop loss and performance loss by the plurality of track portions. In addition, the productivity of the photolithography process may be further improved by preventing stop loss caused by the transport member by the plurality of transport members and the standby region included in the interface portion.

### BRIEF DESCRIPTION OF THE DRAWINGS

FIG. 1 is a top plan view schematically showing a photolithography apparatus according to an embodiment.

FIG. 2 is a view schematically showing a photolithography process performed by a photolithography apparatus according to an embodiment.

FIG. 3 is a top plan view schematically showing an upper portion and a lower portion of a first track portion included in the photolithography apparatus shown in FIG. 1.

FIG. 4 is a schematic cross-sectional view of the first track portion included in the photolithography apparatus shown in FIG. 1.

FIG. 5 is a top plan view schematically showing an interface portion included in the photolithography apparatus shown in FIG. 1.

FIG. 6 is a flowchart illustrating a method of manufacturing a semiconductor device including a photolithography process according to an embodiment.

FIG. 7 is a flowchart illustrating an operation of a plurality of track portions in a method of manufacturing a semiconductor device according to an embodiment.

FIG. 8 is a flowchart illustrating an operation of a plurality of transport members in a method of manufacturing a semiconductor device according to an embodiment.

FIG. 9 is a top plan view schematically showing a photolithography apparatus according to another embodiment.

FIG. 10 is a top plan view schematically showing a track portion included in a photolithography apparatus according to yet another embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiments provided herein.

A portion unrelated to the description is omitted in order to clearly describe the present disclosure, and the same or similar components are denoted by the same reference numeral throughout the present specification.

Further, since sizes and thicknesses of portions, regions, members, units, layers, films, etc., shown in the accompanying drawings may be arbitrarily shown for better understanding and ease of description, the present disclosure is not limited to the illustrated sizes and thicknesses. Thicknesses of some portions, regions, members, units, layers, films, etc., may be enlarged in the drawings in order to clarity. In addition, in the drawings, thicknesses of portions, regions, members, units, layers, films, etc., may be exaggerated for convenience of explanation.

It will be understood that when a component such as a layer, film, region, or substrate is referred to as being “on” another component, it may be directly on other component or intervening components may also be present. In contrast, when a component is referred to as being “directly on” another component, there are no intervening components present. Further, when a component is referred to as being “on” or “above” a reference component, a component may be positioned on or below the reference component, and does not necessarily be “on” or “above” the reference component toward an opposite direction of gravity.

In addition, unless explicitly described to the contrary, the word “comprise” or “include”, and variations such as “comprises”, “comprising”, “includes”, “or including”, will be understood to imply the inclusion of other components rather than the exclusion of any other components.

Further, throughout the specification, a phrase “on a plane” or “in a plane” may indicate a case where a portion is viewed from above or a top portion, and a phrase “on a cross-section” or “in a cross-section” may indicate when a cross-section taken along a vertical direction is viewed from a side.

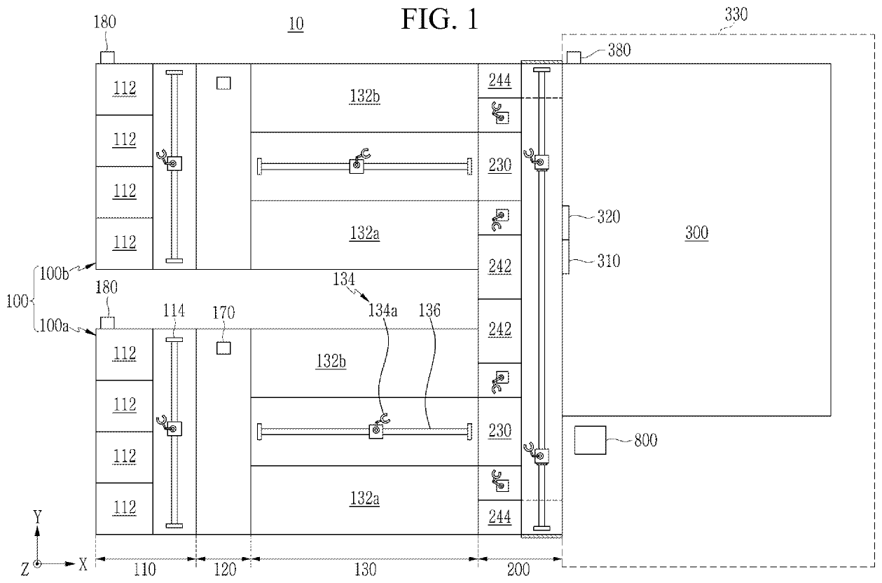

Hereinafter, a photolithography apparatus, an operation method thereof, and a method of manufacturing a semiconductor device according to an embodiment will be described in detail with reference to FIG. 1 to FIG. 8.

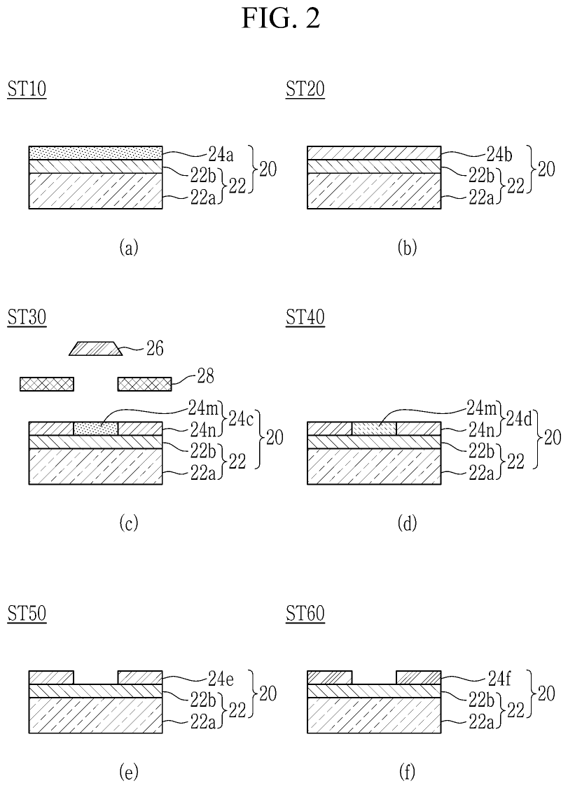

FIG. 1 is a top plan view schematically showing a photolithography apparatus according to an embodiment. FIG. 2 is a view schematically showing a photolithography process performed by a photolithography apparatus according to an embodiment.

Referring to FIG. 1, a photolithography apparatus 10 according to an embodiment has an in-line type in which a photolithography process is sequentially performed. The photolithography apparatus 10 includes a exposure portion 300 in which an exposure process is performed, a plurality of track portions 100 in which a coating process, a developing process, and the like are performed, and an interface portion 200 connecting the exposure portion 300 and the plurality of track portions 100 and transferring a substrate (referring to a numeral number 20 of FIG. 2) between the exposure portion 300 and the plurality of track portions 100. The photolithography apparatus 100 may further include an integrated controller 800 for integrally controlling the exposure portion 300 and the plurality of track portions 100.

The photolithography apparatus 10 according to the embodiment performs a photolithography process to form a final photoresist pattern 24f on a substrate 20, as shown in FIG. 2. The photoresist pattern 24f may be a photomask pattern for patterning at least one of one or a plurality of base layers 22b provided on the substrate 20.

In this specification, the substrate 20 may refer to a member on which a photolithography process is performed. For example, the substrate 20 may be an original substrate 22 in which one or a plurality of base layers 22b are formed on a base substrate 22a by a deposition or the like. Also, the substrate 20 may be a substrate in which a photoresist layer 24a in a liquid state, a photoresist layer 24b in a solid state, an exposed photoresist layer 24c, a post-exposure baked photoresist layer 24d, a developed photoresist pattern 24e, or a final photoresist pattern 24f is positioned on the original substrate 22. Here, the base substrate 22a may be a semiconductor substrate (e.g., wafer), and one or a plurality of base layers 22b may include layers such as an insulation layer, a metal layer, or the like including any of various materials. However, an embodiment is not limited thereto, and materials of the base substrate 22a and the base layer 22b may be variously modified.

In further detail, in the photolithography process, as shown in (a) of FIG. 2, in a coating step (ST10), a coating process may be performed to form a photoresist layer 24a on a base layer 22b formed on the base substrate 22a. For example, in the coating process, the photoresist layer 24a may be in a liquid state. Next, as shown in (b) of FIG. 2, in a soft bake step (ST20), a soft bake process may be performed to convert the photoresist layer 24a in the liquid state into a photoresist layer 24b in a solid state.

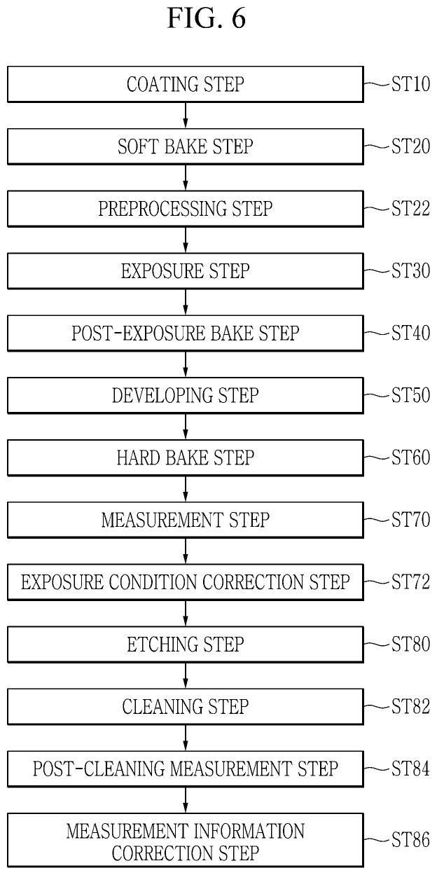

Subsequently, as shown in (c) of FIG. 2, in an exposure step (ST30), an exposed photoresist layer 24c including an exposed region 24m and a non-exposure region 24n may be formed by performing an exposure process. For example, light provided from a light source 26 may be provided to a part of the photoresist layer 24b by using a mask 28. A region of the photoresist layer 24b where the light is provided through an opening of the mask 28 may constitute the exposure region 24m of the exposed photoresist layer 24c, and the other region of the photoresist layer 24b where the light is blocked and is not supplied by the mask 28 may constitute the non-exposure region 24n of the exposed photoresist layer 24c. According to an embodiment, a preprocessing step (a reference numeral ST22 of FIG. 6, hereinafter the same) may be included prior to the exposure step ST30 to perform a preprocessing process such as an edge exposure process, a cleaning process, or the like. Next, as shown in (d) of FIG. 2, in a post-exposure bake step ST40, a post-exposure bake process may be performed to form a post-exposure baked photoresist layer 24d. The post-exposure bake process may be a bake process for accelerating a chemical action of the post-exposure baked photoresist layer 24d. However, an embodiment is not limited thereto.

Subsequently, as shown in (e) of FIG. 2, in a developing step ST50, the exposure region 24m or the non-exposure region 24n may be selectively removed by a developing process. As one example, as shown in (e) of FIG. 2, the exposure region 24m may be removed in the developing process. Then, the developed photoresist pattern 24e may be composed of the non-exposure region 24n. As another example, the non-exposure region 24n may be removed in the developing process. Then, the developed photoresist pattern 24e may be composed of the exposure region 24m. Next, as shown in (f) of FIG. 2, a solvent of the developed photoresist pattern 24e may be removed by a hard bake process to form a photoresist pattern 24f in a final state.

As described above, the photolithography apparatus 10 according to the embodiment may be configured as an in-line type that sequentially performs a plurality of processes included in the photolithography process. As described above, in the photolithography apparatus 10 having the in-line type, an exposure portion 300 performing the exposure process and a plurality of track portions 100 performing the coating process, the developing process, the bake process, etc., may be sequentially disposed while forming a certain arrangement.

Each of the plurality of track portions 100 may perform processes except for the exposure step ST30 in the photolithography process. Also, each of the plurality of track portions 100 may not perform the preprocessing step ST22. However, an embodiment is not limited thereto, and each of the plurality of track portions 100 may perform at least part of the preprocessing step ST22.

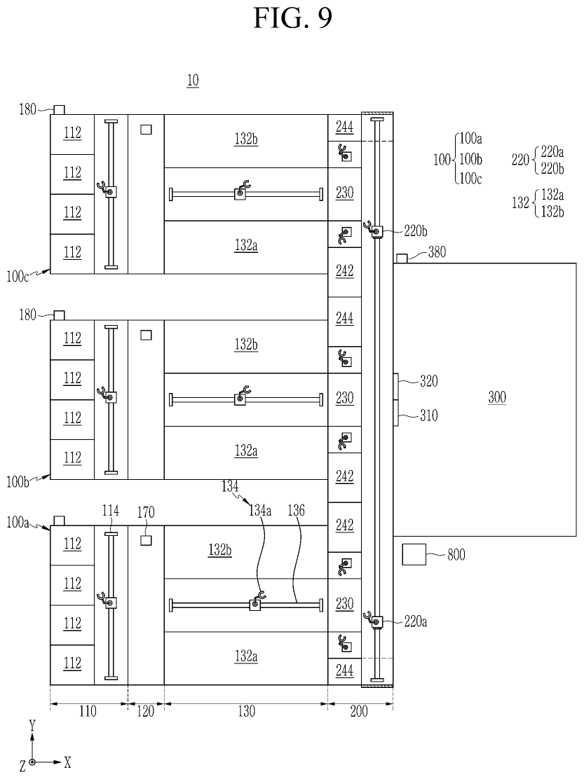

For brief illustration and clear understanding, it is illustrated that the plurality of track portions 100 include first and second track portions 100a and 100b in FIG. 1, and it is described that the plurality of track portions 100 includes the first and second track portions 100a, and 100b in the following description, as an example. However, the embodiment is not limited thereto, and a number of the track portions included in the plurality of track portions 100 is not limited. Therefore, a plurality of track portions 100 may include three or more track portions, and an example thereof will be described with reference to FIG. 9 later in detail.

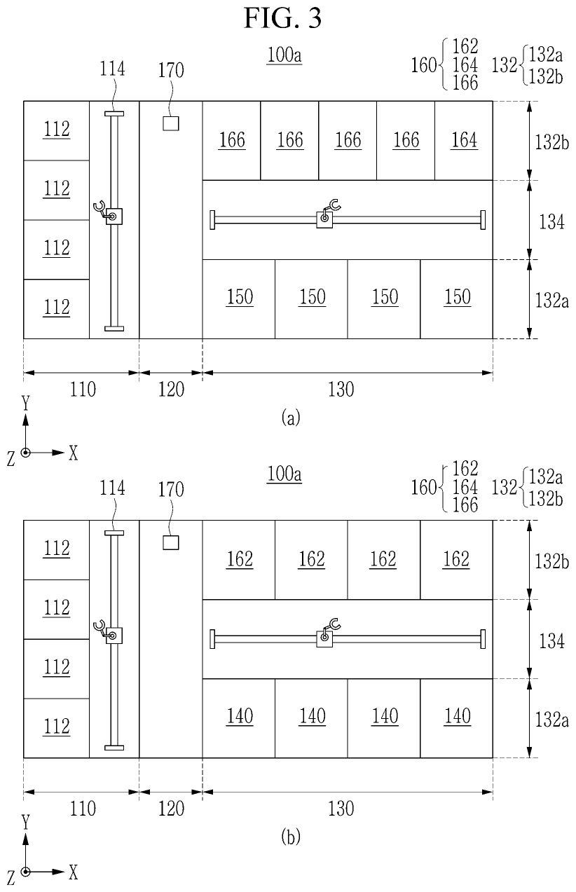

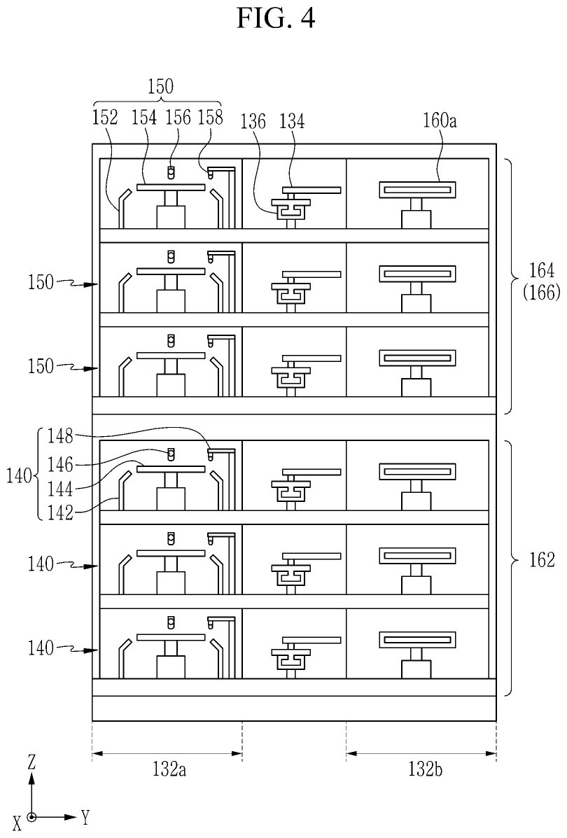

Hereinafter, a structure of each track portion included in the plurality of track portions 100 will be described in detail with reference to FIG. 3 and FIG. 4 along with FIG. 1 and FIG. 2. Here, a structure of each track portion included in the plurality of track portions 100 will be described with reference to the first track portion 100a. That is, description of the first track portion 100a below may be applied to each track portion (e.g., the second track portion 100b, a third track portion 100c shown in FIG. 9, etc.) included in the plurality of track portions 100.

FIG. 3 is a top plan view schematically showing an upper portion and a lower portion of a first track portion included in the photolithography apparatus shown in FIG. 1. FIG. 4 is a schematic cross-sectional view of the first track portion included in a photolithography apparatus shown in FIG. 1.

In an embodiment, the first track portion 100a may include an index portion 110, a buffer portion 120, and a process portion 130. The process portion 130 may include a process member 132 and a process transport member 134.

The index portion 110 is a portion where a substrate 20 is loaded and unloaded. The index portion 110 may be positioned at one side (a left side of FIG. 1) of the track portion 100 in a first direction (an X-axis direction of the drawing). In the index portion 110, a substrate (in further detail, an original substrate 22) on which a photoresist pattern 24f will be formed and/or a substrate 20 on which the photoresist pattern 24f was formed may be positioned in plurality. For example, in the index portion 110, a plurality of placement tables 112 may be provided in a second direction (a Y-axis direction of the drawing). The substrate 20 may be received and positioned in a carrier (not shown) and be positioned at the placement table 112. The index portion 110 may include an index transport member 114 that is positioned at the other side of the placement table 112 in the first direction and moves the substrate 20. When the substrate 20 (more particularly, the original substrate 22) is loaded, the index transport member 114 may separate the substrate 20 from the carrier and transfer the substrate 20 to the buffer portion 120. The index transport member 114 may transfer the substrate 20 to be unloaded (more particularly, the substrate 20 in which the photoresist pattern 24f is formed) from the buffer portion 120 to the index portion 110. The index transport member 114 may have any of various structures capable of transferring the substrate 20. However, an embodiment is not limited thereto, and the index portion 110 may have any of various structures and types. A description of a process transport member 134 may be applied to the index transport member 114.

The buffer portion 120 may be positioned on the other side (a right side of FIG. 1) of the index portion 110 in the first direction (the X-axis direction of the drawing). The buffer portion 120 may be a space where the substrate 20 (more particularly, the original substrate 22) inflowed from the index portion 110 is waited (i.e., held) before being transferred to the process portion 130, and/or a space where the substrate 20 (more particularly, the substrate 20 including the photoresist pattern 24f) transferred from the process portion 130 is positioned before being drawn out (i.e., moved) to the index portion 110. For example, a passage through which the substrate 20 enters the buffer portion 120 and a passage through which the substrate 20 is drawn are separately provided to efficiently operate a workflow. A cooling member (not shown) may be provided in the buffer portion 120 to cool the substrate 20 subjected to a bake process (e.g., a hard bake process). However, an embodiment is not limited thereto, and the buffer portion 120 may have any of various structures and shapes.

The process portion 130 may be positioned on the other side (the right side of FIG. 1) of the buffer portion 120 in the first direction (the X-axis direction of the drawing). For example, in the process portion 130, the process members 132, that is, first and second process members 132a and 132b may be positioned on both sides in the second direction (the Y-axis direction of the drawing) intersecting (i.e., transverse to) the first direction, and a process transport member 134 may be positioned between the first and second process members 132a and 132b. The first and second process members 132a and 132b may each be extended in the first direction, and the process transport member 134 positioned between them may be extended in the first direction, as illustrated.

For example, the first process member 132a may include a coating portion 140 and a developing portion 150, and the second process member 132b may include a bake portion 160.

In the coating portion 140, the coating step ST10 shown in (a) of FIG. 2 may be performed. In the developing portion 150, the developing step ST50 shown in (e) of FIG. 2 may be performed. The bake portion 160 may include a soft bake portion 162 performing the soft bake step ST20 shown in (b) of FIG. 2, a post-exposure bake portion 164 performing the post-exposure bake step ST40 shown in (d) of FIG. 2, and a hard bake portion 166 performing the hard bake step ST60 shown in (f) of FIG. 2.

Each coating portion 140 may have any of various structures capable of coating a photoresist material on the substrate 20. For example, each coating portion 140 may include a housing 142, a supporting plate 144 positioned inside the housing 142 to support the substrate 20, and a nozzle 146 providing a photoresist material to the substrate 20 positioned on the supporting plate 144. For example, the supporting plate 144 may be rotatable, and the nozzle 146 may supply the photoresist material to a center of the substrate 20. According to an embodiment, a cleaning nozzle 148 providing a cleaning material for cleaning a surface of the substrate 20 to which the photoresist material is applied may be further provided.

Each developing portion 150 may have any of various structures to apply a developing material onto the substrate 20. For example, each developing portion 150 may include a housing 152, a supporting plate 154 positioned inside the housing 152 to support the substrate 20, and a nozzle 156 providing a developing material to the substrate 20 positioned on the supporting plate 154. For example, the supporting plate 154 may be rotatable, and the nozzle 156 may supply the developing material to a center of the substrate 20. According to an embodiment, a cleaning nozzle 158 providing a cleaning material for cleaning a surface of the substrate 20 to which the developing material is applied may be further provided.

The bake portion 160 may have any of various structures capable of performing various bake processes on the substrate 20. The bake portion 160 may include a heating plate 160a having a heating member such as a hot wire or a thermoelectric element to heat-treat the substrate 20. Although not shown in the drawing, the bake portion 160 may further include a cooling plate having a cooling member such as a cooling water or a thermoelectric element. The cooling plate may cool the substrate 20 heated by the heating plate 160a in the bake process. Each bake portion 160 may include the heating plate 160a and the cooling plate, respectively, or at least one of the bake portions 160 may include a heating plate 160a without a cooling plate. Alternatively, some of the bake portions 160 may include heating plates 160a and other portions may include cooling plates. Other numerous variations are possible.

The soft bake portion 162, the post-exposure bake portion 164, and the hard bake portion 166 included in the bake portion 160 may heat-treat the substrate 20 at a temperature suitable for the soft bake process, the post-exposure bake process, and the hard bake process, respectively. Although not shown in the drawing, the bake portion 160 may further include a pre-bake portion. The pre-bake portion may perform a pre-bake process before the coating step ST10 in which the photoresist layer 24a in a liquid state is formed. In the pre-bake process, the substrate 20 (more particularly, the original substrate 22) is heated to a certain temperature to remove an organic material and moisture from a surface of the substrate 20. The process transport member 134 positioned between the first process member 132a and the second process member 132b may move along the first direction on a guide rail 136. In the process transport member 134, a portion including a fixing portion 134a supporting or fixing the substrate 20 may move freely in the first direction (the X-axis direction of the drawing), the second direction (the Y-axis direction of the drawing), and a third direction (a Z-axis direction of the drawing), and/or the rotation direction. As a result, the process transport member 134 may smoothly transfer the substrate 20 between the index portion 110 and the process portion 130, transfer the substrate 20 between the first process member 132a and the second process member 132b, and transfer the substrate 20 between the process portion 130 and the exposure portion 300. In the drawing, it is illustrated that the fixing portion 134a has a C-shape formed along a part of an edge of the substrate 20, but the embodiment is not limited thereto. A shape of the fixing portion 134a, and a structure, type, or the like of the process transport member 134 may be variously modified.

In an embodiment, as shown in FIG. 3 and FIG. 4, a plurality of coating portions 140 may be provided in each of the first direction (the X-axis direction of the drawing) and the third direction (the Z-axis direction of the drawing). A plurality of developing portions 150 may be provided in each of the first direction (the X-axis direction of the drawing) and the third direction (the Y-axis direction of the drawing). A plurality of bake portions 160 may be provided in each of the first direction (the X-axis direction of the drawing) and the third direction (the Z-axis direction of the drawing).

For example, when viewed in the third direction or a vertical direction, at an upper portion of the first track portion 100a, the first process member 132a may include one or a plurality of developing portions 150, and the second process member 132b may include one or a plurality of post-exposure bake portions 164 and one or a plurality of hard bake portions 166.

When viewed in a plan view, at the upper portion of the first track portion 100a, the first process member 132a may include a plurality of developing portions 150 in the first direction, and the second process member 132b may include a plurality of hard bake portions 166 and one or a plurality of post-exposure bake portions 164 in the first direction. For example, in the first direction, the plurality of developing portions 150 and the plurality of hard bake portions 166 may be disposed to correspond to each other (e.g., to have one-to-one correspondence). In addition, the post-exposure bake portion 164 may be positioned adjacent to the interface portion 200, and the hard bake portion 166 may be positioned between the post-exposure bake portion 164 and the buffer portion 120. According to this, the post-exposure bake portion 164 in which the post-exposure bake process is performed may be positioned close to the exposure portion 300 to minimize a delay time between the exposure process and the post-exposure bake process.

When viewed in a plan view, at a lower portion of the first track portion 100a, the first process member 132a may include a plurality of coating portions 140 in the first direction, and the second process member 132b may include a plurality of soft bake portions 162 in the first direction. For example, in the first direction, the plurality of coating portions 140 and the plurality of soft bake portions 162 may be disposed to correspond to each other (e.g., to have one-to-one correspondence).

According to this, a large number of substrates 20 may be processed by the plurality of coating portions 140, the plurality of developing portions 150, and the plurality of bake portions 160 provided in the first direction and the third direction, thereby improving a productivity.

In the third direction or the vertical direction, the coating portion 140 and the soft bake portion 162 related to the coating portion 140 are positioned separately from the developing portion 150 and the post-exposure bake portion 164 and the hard bake portion 166 related to the developing portion 150, thereby reducing a travel distance or time of the substrate 20 in the photolithography process.

More particularly, the substrate 20, on which the coating process has been performed in the coating portion 140 of the first process member 132a, may move to the soft bake portion 162 of the second process member 132b corresponding to the above coating portion 140 through the process transport member 134. Then, the substrate 20, on which the coating process and the soft bake process have been sequentially performed, may be moved in a relatively short second direction (the Y-axis direction of the drawing) in the track portion 100, so that the moving distance or time of the substrate 20 may be reduced.

Similarly, the substrate 20, on which the developing process are performed in the developing portion 150 of the first process member 132a, may be moved to the post-exposure bake portion 164 of the second process member 132b corresponding to the above developing portion 150 through the process transport member 134. Then, the substrate 20, on which the developing process and the post-exposure bake process are sequentially performed, may be moved in the relatively short second direction (the Y-axis direction of the drawing) in the track portion 100, so the moving distance or time of the substrate 20 may be reduced.

In addition, the soft bake portion 162, the post-exposure bake portion 164, and the hard bake portion 166 performing the bake process are positioned on the second process member 132b positioned on one side, thereby simplifying a structure of the bake portion 160 or the process portion 130 and improving bake efficiency.

However, an embodiment but is not limited thereto. Therefore, an arrangement of the coating portion 140, the developing portion 150, and the bake portion 160 included in the process portion 130 may be variously modified.

For example, contrary to the embodiment, in the third direction or the vertical direction, the coating portion 140 and the soft bake portion 162 related thereto may be positioned on the upper portion, and the developing portion 150 and the post-exposure bake portion 164 and the hard bake portion 166 related thereto may be positioned on the lower portion. As another example, in the third direction or the vertical direction, the coating portion 140 and the soft bake portion 162 may be positioned separately from the developing portion 150, the post-exposure bake portion 164, and the hard bake portion 166, but an arrangement may be different from that described above.

For example, a number of coating portions 140 and a number of soft bake portions 162 may be different from each other. A number of developing portions 150 and a number of pluralities of hard bake portions 166 may be different from each other. The post-exposure bake portion 164 may be positioned farther from the interface portion 200 than the hard bake portion 166. A number of the post-exposure base portion 164 and a number of the hard bake portion 166 may be variously modified.

For example, the coating portion 140, the soft bake portion 162, the post-exposure bake portion 164, the developing portion 150, and the hard bake portion 166, which perform sequential processes, are sequentially positioned in the first direction (the X-axis direction of drawing). Other numerous variations are possible.

In an embodiment, the first track portion 100a may include a measurement portion 170 capable of measuring a critical dimension of the photoresist pattern 24f. The measurement portion 170 may measure the critical dimension of the photoresist pattern 24f after the hard bake process. For example, the measurement portion 170 may be an image apparatus (e.g., a 3D image apparatus) that takes of a photograph of the substrate 20. For example, the measurement portion 170 may have a laser imaging type (i.e., the measurement portion 170 may have laser imaging capability). As such, by measuring the critical dimension of the photoresist pattern 24f inside the first track portion 100a, a measurement process or a measurement step (a reference number ST70 in FIG. 6) may be performed at a degree that does not interfere with productivity of the photolithography process.

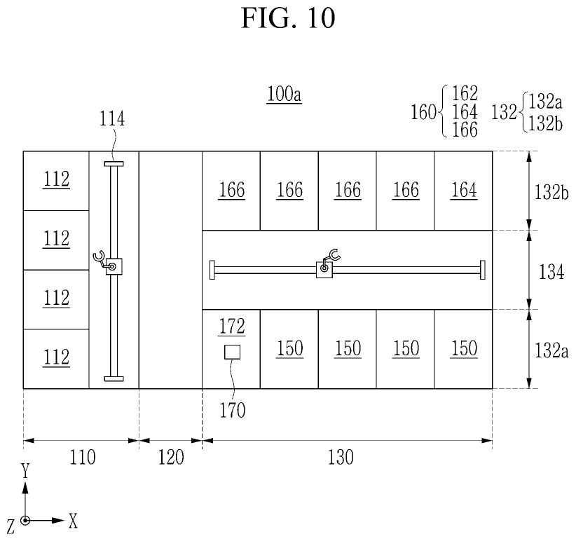

For example, the measurement portion 170 may be provided in the buffer portion 120. Then, when the substrate 20 having the photoresist pattern 24f is positioned in the buffer portion 120, the critical dimension of the photoresist pattern 24f may be measured. According to this, the critical dimension may be measured during the waiting time before the substrate 20 is unloaded, so there is no need to require additional time for the measurement process. However, the embodiment is not limited thereto, and the measurement portion 170 may be provided in any of various positions. Another embodiment is described later with reference to FIG. 10.

The first track portion 100a may include a track controller 180 that controls the index portion 110, the buffer portion 120, the process portion 130, and the measurement portion 170 included in the first track portion 100a. For example, the track controller 180 may receive various information or signals from the index transport member 114 and the process transport member 134 included in the first track portion 100a and provide various signals to them to control their operations. The track controller 180 may receive various information or signals from the process member 132, adjust a process condition of the process member 132, or control whether the process member 132 operates or not. The track controller 180 may control a measurement operation of the measurement portion 170, receive measured information from the measurement portion 170, and provide the information to an exposure controller 380 or an integrated controller 800.

In an embodiment, the track controller 180 may control the interface portion 200 together, which will be described in detail later.

As described above, the description of the first track portion 100a may be applied to the second track portion 100b. That is, the second track portion 100b may include an index portion 110, a buffer portion 120, a process portion 130, a measurement portion 170, and a track controller 180, etc., and the process portion 130 may include a process member 132 and a process transport member 134. The description for the first track portion 100a may be applied for the index portion 110, the buffer portion 120, the process portion 130 including the process member 132 and the process transport member 134, the measurement portion 170, and the track controller 180 of the second track portion 100b.

In an embodiment, the first track portion 100a and the second track portion 100b included in the plurality of track portions 100 may have the same or similar structure, but the embodiment is not limited thereto. Therefore, there may be a difference in structure, type, etc., of the first and second track portion 100a, and 100b included in the plurality of track portions 100 according to an embodiment. For example, the first track portion 100a and the second track portion 100b may have a difference in an arrangement, a number, or the like of the process member 132. Other numerous variations are possible.

The plurality of track portions 100 (e.g., the first track portion 100a and the second track portion 100b) may be spaced apart from each other in the second direction (the Y-axis direction of the drawing). Accordingly, when the plurality of track portions 100 are provided, a path for accessing the first process member 132a and the second process member 132b respectively included in the plurality of track portions 100 may be secured and used for maintenance and the like. That is, a space positioned between the plurality of track portions 100 spaced apart from each other in the second direction may be used as a passage accessible by users, administrators, and the like. However, the embodiment is not limited thereto, and at least a part of the plurality of track portions 100 may be positioned adjacent to each other.

For example, a virtual center line of the plurality of track portions 100 may be positioned apart from a virtual center line of the exposure portion 300 in the second direction. That is, in FIG. 1, the plurality of track portions 100 may be positioned to be biased or deviated to one side (a lower side of the drawing) of the exposure portion 300. According to this, a wider space may be provided on one side (the lower side of the drawing) of the exposure portion 300 to sufficiently secure a maintenance region 330 where an equipment for repair and maintenance of the photolithography apparatus 10 may be positioned. However, the embodiment is not limited thereto, and relative positions of the plurality of track portions 100 and the exposure portion 300 may be variously modified.

The interface portion 200 may transfer the substrate 20 between the plurality of track portions 100 and the exposure portion 300 by connecting the plurality of track portions 100 and the exposure portion 300 (e.g., one exposure portion 300). For example, the plurality of track portions 100 spaced apart from each other in the second direction may be positioned on one side (a left side of FIG. 1) of the interface portion 200 in the first direction, and one exposure portion 300 may be positioned on the other side (a right side of FIG. 1) of the interface portion 200 in the first direction.

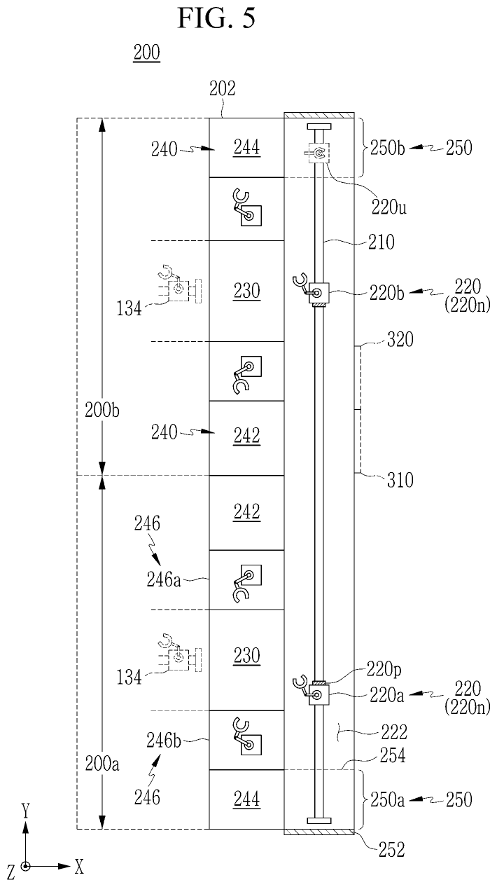

The interface portion 200 is described in detail with reference to FIG. 5 together FIG. 1 to FIG. 4. FIG. 5 is a top plan view schematically showing the interface portion 200 included in the photolithography apparatus 10 shown in FIG. 1.

In an embodiment, the interface portion 200 may be composed of a single main body 202 in which a plurality of track portions 100 are connected to one side in the first direction (the X-axis direction of the drawing) and the exposure portion 300 is connected to the other side in the first direction. In this way, since the interface portion 200 is composed of the single main body 202, a structure of the interface portion 200 may be simplified. However, the embodiment is not limited thereto, and the main body 202 of the interface portion 200 may be modified in various ways such as including a plurality of main body portions.

The interface portion 200 may include a common rail 210 and a plurality of transport members 220, and may further include a buffer portion 230, a preprocessing portion 240, and a standby region 250. In the interface portion 200, a plurality of processing portions 200a and 200b each including the buffer portion 230 and the preprocessing portion 240 may be provided to correspondence to the plurality of track portions 100 (e.g., to have one-to-one correspondence). For example, the processing portion 200a and 200b may include a first processing portion 200a corresponding to the first track portion 100a and a second processing portion 200b corresponding to the second track portion 100b.

The buffer portion 230 may be positioned on one side adjacent to the plurality of track portions 100 in the first direction, and may be provided in plural to each correspond to the plurality of track portions 100 (e.g., to have one-to-one correspondence). Each plurality of buffer portions 230 may be positioned to correspond to the process transport members 134 of the plurality of track portions 100, respectively. For example, the buffer portion 230 of the first processing portion 200a may be positioned to correspond to the process transport member 134 of the first track portion 100a, and the buffer portion 230 of the second processing portion 200b may be positioned to correspond to the process transport member 134 of the second track portion 100b.

The buffer portion 230 may be a space where the substrate 20 inflowed from the track portion 100 to the interface portion 200 is positioned before being transferred to the preprocessing portion 240 or the exposure portion 300, and/or a space where the substrate 20 transferred from the exposure portion 300 is positioned before being transferred to the track portion 100.

For example, a plate (not shown) positioned at the buffer portion 230 and supporting the substrate 20 have a tower structure that may move in the third direction or the vertical direction to correspond to the plurality of process transport members 134 positioned in the third direction (the Z-axis direction of the drawing) or the vertical direction. Then, the substrate 20 may be smoothly transferred between the plurality of process transport members 134 and the buffer portion 230 positioned in the third direction. However, an embodiment is not limited thereto, and a structure and a shape of the buffer portion 230 may be variously modified.

In an embodiment, a preprocessing portion 240 may be provided on at least one side of the buffer portion 230 in the second direction at one side of the interface portion 200 adjacent to the plurality of track portions 100 in the first direction. A preprocessing transport member 246 transferring the substrate 20 may be provided between the buffer portion 230 and the preprocessing portion 240. According to this, a space of the interface portion 200 may be maximally utilized.

For example, a plurality of preprocessing portions 240 may be provided to correspond to the plurality of track portions 100 (e.g., to have one-to-one correspondence). For example, the preprocessing portion 240 may be provided on at least one side of the buffer portion 230 in the first processing portion 200a, and the preprocessing portion 240 may be provided on at least one side of the buffer portion 230 in the second processing portion 200b.

The preprocessing portion 240 may perform a preprocessing process or a preprocessing step (a reference numeral ST22 in FIG. 6) to prevent a contamination of the exposure portion 300 by preprocessing the substrate 20 before inflow of the substrate 20 into the exposure portion 300. For example, the preprocessing portion 240 may include an edge exposure portion 242 positioned on one side of the buffer portion 230 and a cleaning portion 244 positioned on the other side of the buffer portion 230 in the second direction. The preprocessing portion 240 may further include first and second preprocessing transport members 246a and 246b between the buffer portion 230 and the edge exposure portion 242 and between the buffer portion 230 and the cleaning portion 244, respectively.

The edge exposure portion 242 may perform an edge exposure process of additionally exposing an edge portion of the substrate 20 before transferring the substrate 20 to the exposure portion 300. The cleaning portion 244 may perform a cleaning process that cleans the substrate 20. The edge exposure portion 242 may have any of various structures capable of performing an edge exposure process, and the cleaning portion 244 may have any of various structures capable of performing a cleaning process.

In the illustrated embodiment, the preprocessing portion 240 is shown as including the cleaning portion 244 and the edge exposure portion 242, but the embodiment is not limited thereto. At least one of the edge exposure portion 242 and the cleaning portion 244 may not be included, and a separate portion for preprocessing of the substrate 20 may be further included in addition to the edge exposure portion 242 and/or the cleaning portion 244.

The common rail 210 may longitudinally extend in the second direction (the Y-axis direction of the drawing) to correspond to the plurality of track portions 100 at the other side adjacent to the exposure portion 300 in the first direction (the X-axis direction of the drawing), and may provide a path where a plurality of transport members 220 move. The common rail 210 may be extended so that the plurality of transport members 220 may access the plurality of buffer portions 230 corresponding to at least the plurality of track portions 100. Accordingly, the plurality of transport members 220 may stably access the plurality of the buffer portions 230 corresponding to the plurality of track portions 100, respectively.

Since the common rail 210 is positioned adjacent to the exposure portion 300, the substrate 20 on which the preprocessing process has been performed may be easily transferred between the preprocessing portion 240 and the exposure portion 300. However, an embodiment is not limited to this and numerous variations are possible.

For example, the plurality of transport members 220 may be provided to correspond to the plurality of track portions 100 (e.g., to have one-to-one correspondence). Then, since each transport member 220 is driven corresponding to each track portion 100, the substrate 20 may be stably transferred between the plurality of track portions 100 and the exposure portion 300.

For example, the plurality of transport members 220 may include a first transport member 220a corresponding to the first track portion 100a and a second transport member 220b corresponding to the second track portion 100b. The first transport member 220a may move between the buffer portion 230 of the first processing portion 200a and the exposure portion 300 to provide the substrate 20 of the buffer portion 230 of the first processing portion 200a to an inlet portion 310 of the exposure portion 300, or to provide the substrate 20 discharged from an outlet portion 320 of the exposure portion 300 to the buffer portion 230 of the first processing portion 200a. The second transport member 220b may move between the buffer portion 230 of the second processing portion 200b and the exposure portion 300 to provide the substrate 20 of the buffer portion 230 of the second processing portion 200b to the inlet portion 310 of the exposure portion 300, or to provide the substrate 20 discharged from the outlet portion 320 of the exposure portion 300 to the buffer portion 230 of the second processing portion 200b.

However, the embodiment is not limited thereto, and a number of the plurality of transport members 220 may not correspond to a number of the plurality of track portions 100. That is, the number of the plurality of transport members 220 may be less than the number of plurality of track portions 100, or the number of plurality of transport members 220 may be greater than the number of plurality of track portions 100. An example of this will be described in detail with reference to FIG. 9.

At least one of the plurality of transport members 220 may have a bumper portion 220p positioned adjacent to another transport member. The bumper portion 220p may be formed of a buffer member, a cushioning member, or a shock-absorbing member formed to prevent the plurality of transport members 220 from impacting or damaging each other when the plurality of transport members 220 contact each other. Alternatively, the bumper portion 220p may be formed of a spacing member that prevents the plurality of transport members 220 from contacting each other in a non-contact manner. For example, the spacing member may be composed of a magnetic material or the like.

Each transport member 220 may move along the second direction on the common rail 210. In the transport member 220, a portion including a fixing portion supporting or fixing the substrate 20 move freely in the first direction (the X-axis direction of the drawing), the second direction (the Y-axis direction of the drawing), the third direction (the Z-axis direction of the drawing), and/or a rotation direction. Accordingly, the transport member 220 may smoothly transfer the substrate 20 between the buffer portion 230 and the exposure portion 300. In the drawing, it is illustrated that the fixing portion has a C-shape formed along a part of an edge of the substrate 20, but the embodiment is not limited thereto. A shape of the fixing portion, a structure, type, or the like of the transport member 220 may be variously modified.

For example, the common rail 210 may be composed of one rail that extends from one side to the other side in the second direction. A standby region 250 in which at least one of the plurality of transport members 220 may be positioned may be provided on at least one end side of the common rail 210. The standby region 250 may be a region in which an abnormal transport member 220u in an abnormal state requiring an inspection or a repair among the plurality of transport members 220 stands by until the inspection or the repair is performed. The term “abnormal transport member”, as used herein, means a transport member that is malfunctioning or otherwise not operating properly. For a clear understanding, FIG. 5 illustrates the abnormal transport member 220u positioned in the standby region 250 in dotted line. That is, when the abnormal transport member 220u requiring the inspection or the repair is moved to the standby region 250 and positioned in the standby region 250, a normal transport member 220n in a normal state may transfer the substrate 20 between the plurality of track portions 100 and the exposure portion 300.

For example, a first standby region 250a and a second standby region 250b may be respectively positioned at the opposite ends of the common rail 210 in the second direction. Then, the abnormal transport member 220u may be freely moved to the standby region 250 regardless of a position of the abnormal transport member 220u. For example, when the first transport member 220a is the abnormal transport member 220u, the second transport member 220b may move the first transport member 220a to one side (a lower side of the drawing) and move the first transport member 220a to the first standby region 250a. For example, when the second transport member 220b is the abnormal transport member 220u, the first transport member 220a may move the second transport member 220b to the other side (an upper side of the drawing) and move the second transport member 220b to the second standby region 250b.

In this way, when the abnormal transport member 220u is positioned in the standby region 250, the remaining normal transport member 220n may transfer the substrate 20 of the track portion that corresponded by the abnormal transport member 220u. For example, in the state where the first transport member 220a is positioned in the first standby region 250a as the abnormal transport member 220u, the second transport member 220b, which is the normal transport member 220n, takes charge of the transferring of the substrate 20 of the first track portion 100a, which was originally handled by the first transport member 220a, together with the transferring of the substrate 20 of the second track portion 100b, which was originally handled by the second transport member 220b. For example, in the state where the second transport member 220b is positioned in the second standby region 250b as the abnormal transport member 220u, the first transport member 220a, which is the normal transport member 220n, takes charge of transferring the substrate 20 of the second track portion 100b, which was handled by the second transport member 220b, together with the transferring of the substrate 20 of first track portion 100a, which was originally handled by the first transport member 220a.

At least one side of the standby region 250 may be provided with a door member 252 that is opened to connect the standby region 250 to an outside and/or is closed to separate the standby region 250 from the outside. The door member 252 has a form of a kind of a cover, etc., so that a user may open the door member 252 to inspect or repair the abnormal transport member 220u positioned in the standby region 250, or take the abnormal transport member 220u out of the standby region 250 to inspect, repair, or replace the abnormal transport member 220u.

The interface portion 200 may further include a separation member 254 separating the standby region 250 and an internal region 222 other than the standby region 250. The internal region 222 may refer to a region excluding the standby region 250 in a region where the common rail 210 is positioned. The separation member 254 may have any of various structures or types capable of preventing external contaminants from flowing into the interface portion 200. For example, the separation member 254 may be composed of a shutter member positioned between the standby region 250 and the internal region 222, or an air curtain member providing air between the standby region 250 and the internal region 222.

In an embodiment, the track controller 180 may control the interface portion 200 together. That is, the track controller 180 may control the transport member 220, the buffer portion 230, the preprocessing portion 240, and the standby region 250 included in the interface portion 200.

For example, the track controller 180 may receive various information or signals from the transport member 220 and the preprocessing transport member 246 and provide various signals to them to control their operations. The track controller 180 may receive various information or signals from the preprocessing portion 240, adjust a process condition of the preprocessing portion 240, or control whether the preprocessing portion 240 operates or not.

However, an embodiment is not limited thereto. A separate interface controller for controlling the interface portion 200 may be provided.

The exposure portion 300 positioned on the other side of the interface portion 200 in the first direction may provide light to at least a part of the photoresist layer 24b positioned on the substrate 20 to form an exposure region 24m. The remaining portion where the light is not exposed may constitute a non-exposure region 24n. For example, the exposure portion 300 may have any of various structures such as a stepper, a scanner, or a structure in which these are mixed.

The exposure portion 300 may include an inlet portion 310 in which the substrate 20 to be subjected to the exposure process inflows, an outlet portion 320 in which the substrate 20 on which the exposure process has been performed is discharged, and an exposure member (not shown) for performing the exposure process.

The substrate 20 to be subjected to the exposure process is inflowed into the inlet portion 310 by the transport member 220, and the substrate 20 on which the exposure process has been performed may be discharged through the outlet portion 320 by the transport member 220. Any of various structures may be applied to the inflow and/or the discharge of the substrate 20 in the inlet portion 310 and/or the outlet portion 320, or the exposure portion 300.

The exposure member may include any of various members that perform the exposure process, for example, a light source 26, a mask 28, a light path control member (e.g., a lens) (not shown), and the like.

For example, the light source 26 may provide ultraviolet (UV), for example, deep ultraviolet (DUV) or extreme ultraviolet (EUV). When deep ultraviolet or extreme ultraviolet is used as light in the exposure portion 300, a fine pattern of the photoresist pattern 24f may be achieved. However, an embodiment is not limited to a type of light used in the exposure portion 300.

In the exposure portion 300, the light is irradiated through the mask 28 having a pattern on the photoresist layer 24b positioned on the substrate 20. Then, according to the pattern of the mask 28, the exposed photoresist layer 24c has an exposure region 24m exposed by the light and a non-exposure region 24n not exposed by the light. The exposure region 24m and the non-exposure region 24n differ in chemical properties, for example, a solubility. Due to this difference in the chemical properties, one of the exposure region 24m and the non-exposure region 24n may be removed and the other may be not removed to form the developed photoresist pattern 24e in the later developing process.

The exposure portion 300 may include an exposure controller 380 that controls an exposure transport member (not shown) that transfers the substrate 20, the light source 26, or the like included in the exposure portion 300. The exposure controller 380 may receive various information or signals from the exposure transport member and provide various signals to them to control their operations. The exposure controller 380 may receive various information or signals from the light source 26, and adjust the light source 26 or control whether the light source 26 operates or not.

The plurality of track portions 100, the exposure portion 300 and/or the interface portion 200 may be controlled by an integrated controller 800 that integrally controls them. For example, the integrated controller 800 may control the plurality of track controllers 180 respectively controlling the plurality of track portions 100 and the exposure controller 380 controlling the exposure portion 300. Accordingly, the integrated controller 800 may control whether the plurality of track portions 100 operate or not, an order in which the substrate 20 is transferred between the plurality of track portions 100 and the exposure portion 300, and the like.

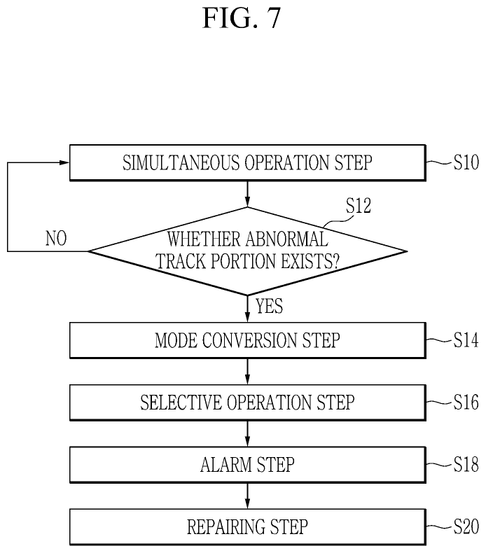

More particularly, in an embodiment, the integrated controller 800 may control whether to operate or stop the plurality of track portions 100 and/or the interface portion 200 according to the state of the plurality of track portions 100. For example, the integrated controller 800 may receive a state signal of the plurality of track portions 100 from the plurality of track controller 180 and generate an operation or stop signal of the plurality of track portions 100 and/or the interface portion 200 and provide to the plurality of track controller 180. Accordingly, the integrated controller 800 simultaneously or selectively operate a plurality of track portions 100, which will be described in more detail with reference to FIG. 7.

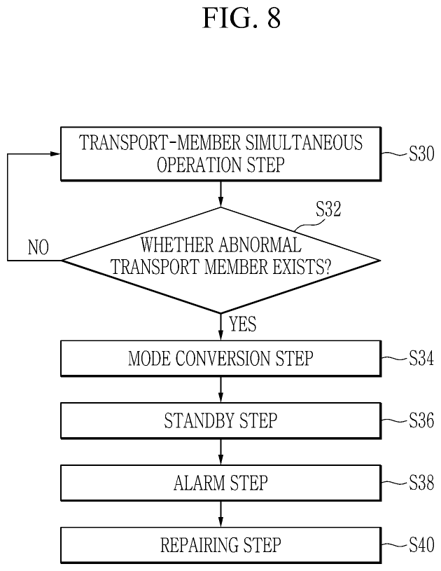

Also, the integrated controller 800 or the plurality of track controllers 180 may control whether the plurality of transport members 220 are operated, moved, or stopped according to a state of the plurality of transport members 220. For example, the integrated controller 800 or plurality of track controller 180 may receive state signals of the plurality of transport members 220 and generate start, move, or stop signals of the plurality of transport members 220 and provide them to the plurality of transport members 220. This is described later in detail with reference to FIG. 8.

For example, the integrated controller 800 may be positioned separately from the plurality of track controllers 180 and the exposure controller 380 and control the plurality of track controllers 180 and the exposure controller 380 by using a wireless communication. However, an embodiment is not limited thereto. Accordingly, the plurality of track controllers 180 and/or the exposure controller 380 may constitute at least a part of the integrated controller 800, or the plurality of track controllers 180 and/or the exposure controller 380 may include at least a part of the integrated controller 800. Other numerous variations are possible.

In FIG. 1, the track controller 180, the exposure controller 380, and the integrated controller 800 are briefly illustrated as an example, and actual positions and structures may be not reflected. For example, it is illustrated that the integrated controller 800 is positioned within the maintenance region 330 in FIG. 1, but this is just for explanation, but the embodiment is not limited thereto.

As such, the photolithography apparatus 10 including the plurality of track portions 100 may be effectively controlled by the integrated controller 800 capable of integrally controlling the plurality of track portions 100 and the exposure portion 300. However, the embodiment is not limited thereto, and the plurality of track portions 100, the interface portion 200, and the exposure portion 300 may be controlled using any of various methods.

An operation method of the above photolithography apparatus 10 and a method of manufacturing a semiconductor device including a photolithography process using the photolithography apparatus 10 will be described, based on one track portion (e.g., the substrate 20 positioned in the first track portion 100a), with reference to FIG. 6 along with FIG. 1 to FIG. 5.

FIG. 6 is a flowchart illustrating a method of manufacturing a semiconductor device including a photolithography process according to an embodiment.

Referring to FIG. 6, a method of manufacturing a semiconductor device according to an embodiment may include a coating step ST10, a soft bake step ST20, an exposure step ST30, a post-exposure bake step ST40, a developing step ST50, a hard bake step ST60, a measurement step ST70, and an exposure condition correction step ST72. A preprocessing step ST22 performed before the exposure step ST30, an etching step ST80 performed, a cleaning step ST82, a post-cleaning measurement step ST84, a measurement information correction step ST86 after the exposure condition correction step ST72, or the like may be further included.

Here, the substrate 20 positioned in the first track portion 100a may be subjected to the preprocessing step ST22 in the first processing portion 200a of the interface portion 200 after the coating step ST10 and the soft bake step ST20 are performed in the first track portion 100a. After that, the substrate 20 moves to the exposure portion 300 and the exposure step ST30 may be performed. Next, the substrate 20 moves to the first track portion 100a again, and the post-exposure bake step ST40, the developing step ST50, the hard bake step ST60, and the measurement step ST70 may be performed.

First, the substrate 20 positioned in the index portion 110 of the track portion 100 may be moved to the coating portion 140 through the process transport member 134 via the buffer portion 120. In the coating portion 140, the coating step ST10 as shown in (a) of FIG. 2 may be performed to the substrate 20.

The substrate 20 having the photoresist layer 24a formed in the coating step ST10 may be transferred to the soft bake portion 162 by the process transport member 134. The soft bake step ST20 as shown in (b) of FIG. 2 may be performed to the substrate 20 in the soft bake portion 162. The substrate 20 on which the soft bake step ST20 has been performed may be moved to the buffer portion 230 of the interface portion 200 by the process transport member 134.

The substrate 20 having the photoresist layer 24b positioned in the buffer portion 230 of the interface portion 200 may be moved to the preprocessing portion 240, and the preprocessing step ST22 may be performed on the substrate 20 in the preprocessing portion 240. For example, the substrate 20 positioned in the buffer portion 230 may be moved to the edge exposure portion 242 in the first preprocessing transport member 246a, and the edge exposure process may be performed on the substrate 20 by the edge exposure portion 242 and be moved to the buffer portion 230 by the first preprocessing transport member 246a. The substrate 20 on which the edge exposure process has been performed may be moved to the cleaning portion 244 by the second preprocessing transport member 246b, and the cleaning process is performed on the substrate 20 in the cleaning portion 244, and be transferred to the buffer portion 230 by the second preprocessing transport member 246b.

The substrate 20 on which the preprocessing step ST22 has been performed may be moved to the inlet portion 310 of the exposure portion 300 by the transport member 220. In the exposure portion 300, as shown in (c) of FIG. 2, the exposure step ST30 may be performed on the substrate 20, thereby forming the exposed photoresist layer 24c. The substrate 20 on which the exposure step ST30 has been performed may be moved from the outlet portion 320 of the exposure portion 300 to the buffer portion 230 by the transport member 220.

The substrate 20 positioned in the buffer portion 230 and having the exposed photoresist layer 24c may be transferred to the post-exposure bake portion 164 by the process transport member 134. In the post-exposure bake portion 164, the post-exposure bake step ST40 as shown in (d) of FIG. 2 is performed on the substrate 20, thereby forming the post-exposure baked photoresist layer 24d.

The substrate 20 on which the post-exposure bake step ST40 has been performed may be transferred to the developing portion 150 by the process transport member 134. In the developing portion 150, the developed photoresist layer 24e may be formed by performing the developing step ST50 as shown in FIG. 2 (e) on the substrate 20.

The substrate 20 on which the developing step ST50 has been performed may be transferred to the hard bake portion 166 by the process transport member 134. In the hard bake portion 166, the hard bake step ST60 as shown in (f) of FIG. 2 is performed on the substrate 20, and then the photoresist pattern 24f of the final state may be formed.

The substrate 20 on which the hard bake step ST60 has been performed may be moved to the buffer portion 120 by the process transport member 134. In the buffer portion 120, a measurement step ST70 for measuring a critical dimension of the photoresist pattern 24f provided on the substrate 20 by the measurement portion 170 may be performed. The critical dimension information of the photoresist pattern 24f measured in the measurement step ST70 may be provided to the exposure portion 300 (e.g., the exposure controller 380) or the integrated controller 800. In the exposure condition correction step ST72 performed after the measurement step ST70, the exposure controller 380 or the integrated controller 800 may correct a exposure condition of the exposure portion 300 by using the critical dimension information of the photoresist pattern 24f.

The critical dimension information of the photoresist pattern 24f measured by the measurement portion 170 is not a critical dimension information after performing the etching step ST80 and the cleaning step ST82, etc., but the critical dimension of the final pattern after performing the etching step ST80 and the cleaning step ST82 may be predicted by using the critical dimension information of the photoresist pattern 24f. In consideration of the predicted value of the critical dimension of the final pattern, the exposure condition of the exposure portion 300 may be corrected in the exposure condition correction step ST72. Accordingly, the exposure condition may be quickly corrected, and a pattern formed by the photolithography process or a quality of a semiconductor device including the pattern may be improved.

After the measurement step ST70, the etching step ST80, the cleaning step ST82, and the post-cleaning measurement step ST84, the measurement information correction step ST86 may be performed. In the post-cleaning measurement step ST84, a critical dimension of a final pattern formed by the photolithography process, that is, an after-clean critical dimension (ACI CD) may be measured. The critical dimension information of the final pattern measured in the measurement step ST84 may be provided to the exposure controller 380 or the integrated controller 800. In the measurement information correction step ST86, the exposure controller 380 or the integrated controller 800 may match the critical dimension information of the final pattern and the critical dimension information of the photoresist pattern 24f of the measurement step ST70 and thus correct the measurement information by a deep learning or the like.

A consistency of the critical dimension information of the photoresist pattern 24f measured by the measurement portion 170 and the critical dimension information of the final pattern measured after the cleaning can be continuously improved by the measurement information correction step ST86. Accordingly, the measurement information measured by the measurement portion 170 may be used to predict or replace the after-clean critical dimension information.

According to the embodiment, by the measurement step ST70 using the measurement portion 170, an exposure correction time may be shortened (e.g., 10 minutes), so that the quality and yield of a semiconductor device manufactured by a semiconductor manufacturing process including the photolithography process may be improved.

On the other hand, conventionally, after performing an etching process, a cleaning process, etc., an after-cleaning critical dimension of each pattern (e.g., a line, a space, a hole, etc.) was measured to confirm whether each pattern was formed in accordance with a design pattern or not. An exposure condition of an exposure portion was corrected through a feedback of an information of an after-cleaning critical dimension to the exposure portion. According to this, since it takes a lot of time (e.g., 2 weeks or more) to correct the exposure condition, a process was performed to the substrate 20 before the correction with a risk of defect occurrence.

In addition, according to the embodiment, since each measurement portion 170 is provided in a plurality of track portions 100, when a change occurs in a measurement value of the critical dimension, by comparing information of the plurality of track portions 100, a portion having a problem can be easily confirmed among the plurality of track portions 100 and the exposure portion 300. For example, if a problem occurs in one of the plurality of track portions 100, a problem may occur in the corresponding track portion. If a problem occurs in all of the plurality of track portions 100, a problem may occur in other portions such as the exposure portion 300. As in the above, when a portion having a problem is quickly identified, a performance loss may be effectively improved. On the other hand, in the prior art, even if a problem occurs, it is difficult to determine whether the problem occurs in the track portion 100 or the exposure portion 300.

As in the above, according to an embodiment, through the measurement portion 170 positioned in the track portion 100, the critical dimension may be measured in real time by using an in-situ process, and the exposure condition of the exposure portion 300 may be optimized therefrom, thereby improving the yield and quality of the semiconductor device.

Similarly, the substrate 20 positioned in the second track portion 100b may be subjected to the preprocessing step ST22 in the second processing portion 200b of the interface portion 200 after the coating step ST10 and the soft bake step ST20 are performed in the second track portion 100b. Next, the substrate 20 moves to the exposure portion 300 and the exposure step ST30 may be performed. Next, the substrate 20 moves to the second track portion 100b again, and then the post-exposure bake step ST40, the developing step ST50, the hard bake step ST60, and the measurement step ST70 may be performed.

The operations of the track portion 100 and/or the interface portion 200 may be controlled by the track controller 180 or the integrated controller 800, and the operation of the exposure portion 300 may be controlled by the exposure controller 380 or the integrated controller 800.

An operation method of the photolithography apparatus 10 regarding a plurality of track portions 100 and a method of manufacturing a semiconductor device using the same will be described as follows. FIG. 7 is a flowchart illustrating an operation of a plurality of track portions in a method of manufacturing a semiconductor device according to an embodiment.

Referring to FIG. 7, in a simultaneous operation step S10, a simultaneous operation mode may be performed. In the simultaneous operation mode, a plurality of track portions 100, which are normal track portions, may be simultaneously operated and an existence of an abnormal track portion may be periodically detected. Here, the normal track portion may refer to a track portion that is operated in a full operation state in which the track portion is fully operated or in a partial operation state in which the track portion is partially operated. The abnormal track portion may refer to a track portion that is inoperable or needs to be stopped for a repair or an inspection.

More particularly, in the simultaneous operation mode, the integrated controller 800 may simultaneously operate the plurality of track portions 100 to perform the photolithography process.

For example, in the simultaneous operation mode, the integrated controller 800 may transmit an operation signal to the plurality of track controllers 180, and the plurality of track controllers 180 may operate the plurality of track portions 100. For example, a first substrate, on which the coating process or the like has been performed in the first track portion 100a, and a second substrate, on which the coating process or the like has been performed in the second track portion 100b, may be alternatively transferred to the exposure portion 300. Thus, the exposure process is alternatively performed to the first substrate and the second substrate. The first substrate, on which the exposure process has been performed, may be moved to the first track portion 100a to perform the developing process, and the second substrate, on which the exposure process has been performed, may be moved to the second track portion 100b to perform the developing process. However, an embodiment is not limited thereto. Therefore, by considering states of the first track portion 100a and the second track portion 100b, an inflow order to the exposure portion 300 or a discharge order from the exposure portion 300 of the first substrate processed by the first track portion 100a and the second substrate processed by the second track portion 100b may be variously changed.

In addition, the integrated controller 800 may periodically detect a state of the plurality of track portions 100 and thus periodically detect whether the plurality of track portions 100 are abnormal or not. For example, the plurality of track controllers 180 included in the plurality of track portions 100 may periodically check the state of the plurality of track portions 100 and provide the state of the plurality of track portions 100 to the integrated controller 800. However, the embodiment is not limited thereto, and the state of the plurality of track portions 100 may be periodically detected by any of various methods.

In an abnormal-track-portion determination step S12, it is determined whether an abnormal track portion exists or not among the plurality of track portions 100. If the abnormal track portion does not exist, the simultaneous operation step S10 may be performed.

If the abnormal track portion exists, the simultaneous operation mode may be converted to a selective operation mode in a mode conversion step S14. In a selective operation step S16, the photolithography process may be performed by the selective operation of stopping the abnormal track portion and operating the remaining track portion or track portions (the normal track portion or the normal track portions). In the selective operation step S16, the processing portions 200a and 200b and/or the transport member 220 corresponding to the abnormal track portion may be stopped together.

For example, in the selective operation mode, the integrated controller 800 may transmit a stop signal to the track controller 180 included in the abnormal track portion and transmit an operating signal to the track controller 180 included in the normal track portion. The substrate 20 on which the exposure process has been performed may be moved to the normal track portion to perform the developing process. Accordingly, even when at least one of the plurality of track portions 100 is the abnormal track portion, the photolithography process may be performed using the remaining normal track portion or track portions.

In an alarm step S18, the integrated controller 800 may generate a warning signal informing of the state of the abnormal track portion and provide the warning signal to a user, manager, etc., through an output portion of the integrated controller 800. Then, the user, manager, etc., may perform a repairing step S20 of repairing, inspecting, or replacing the abnormal track portion.

The simultaneous operation step S10 may be performed after the repairing step S20. Accordingly, a simultaneous operation mode may be performed. In the simultaneous operation mode, a plurality of track portions 100, which are normal track portions, may be simultaneously operated and an existence of an abnormal track portion may be periodically detected.

Accordingly, even when the abnormal track portion is provided, the photolithography process may be performed without stopping of the exposure portion 300. Thus, the exposure portion 300 may be operated in maximum, thereby increasing an operation rate of the exposure portion 300 and improving productivity of the photolithography process or the photolithography apparatus 10.

In Table 1, productivity of a photolithography apparatus 10 including first and second track portions 100a and 100b is shown according to operating conditions of the first and second track portions 100a and 100b. In Table 2, a total operation rate is shown when a full operation, a partial operation, and a stop rate of each track portion are assumed to be 0.7, 0.28, and 0.02, respectively. For comparison, in Note 1 of Table 1, an operation rate of an exposure portion is shown when the first track portion 100a is provided without the second track portion 100b. In Note 2 of Table 1, an operation rate of an exposure portion is shown when the second track portion 100b is provided without the first track portion 110a. In Note 1 of Table 2, a total operation rate is shown when the first track portion 100a is provided without the second track portion 100b. In Note 2 of Table 2, a total operation rate is shown when the second track portion 100b is provided without the first track portion 100a.

TABLE 1

| | | | | Operation | | |
|---|---|---|---|---|---|---|
| | | | | rate of | | |
| | First | Second | Exposure | Exposure | Note | Note |
| | track portion | track portion | portion | portion | 1 | 2 |
| State 1 | Full operation | Full operation | Full | 100% | 100% | 100% |
| | | | operation | | | |
| State 2 | Partial | Full operation | Full | 100% | 70% | 100% |
| | operation (70%) | | operation | | | |
| State 3 | Full operation | Partial | Full | 100% | 100% | 70% |
| | | operation (70%) | operation | | | |
| State 4 | Stop | Full operation | Full | 100% | 0% | 100% |
| | | | operation | | | |
| State 5 | Full operation | Stop | Full | 100% | 100% | 0% |
| | | | operation | | | |
| State 6 | Partial | Partial | Full | 100% | 70% | 70% |
| | operation (70%) | operation (70%) | operation | | | |
| State 7 | Stop | Partial | Partial | 70% | 0% | 70% |
| | | operation (70%) | operation | | | |
| State 8 | Partial | Stop | Partial | 70% | 70% | 0% |
| | operation (70%) | | operation | | | |
| State 9 | Stop | Stop | Stop | 0% | 0% | 0% |

TABLE 2

| | Embodiment | Note 1 | Note 2 |
|---|---|---|---|
| Total operation rate | 99.6% | 89.6% | 89.6% |

Referring to Table 1, compared to Note 1 (the first track portion 100a is used without the second track portion 100b) and Note 2 (the second track portion 100b is used without the first track portion 100a), when the first and second track portions 100a and 100b (that is, a plurality of track portions 100) are used together, it is confirmed that the operation rate of the exposure portion may be increased. Referring to Table 2, it may be confirmed that the total operation rate of the photolithography apparatus according to the embodiment is 99.6%, which is significantly higher than the total operation rate of 89.6% of a conventional case using one track portion (refer to Note 1 and Note 2). Accordingly, it may be confirmed that productivity of the photolithography process may be improved according to the embodiment.

An operation method of a photolithography apparatus 10 and a method of manufacturing a semiconductor device using the same for a plurality of transport members 220 will be described as follows. FIG. 8 is a flowchart illustrating an operation of a plurality of transport members in a method of manufacturing a semiconductor device according to an embodiment.

Referring to FIG. 8, in a transport-member simultaneous operation step S30, a transport-member simultaneous operation mode may be performed. In the transport-member simultaneous operation mode, a plurality of transport members 220, which are normal transport members 220n, may be simultaneously operated and an existence of an abnormal transport member 220u may be periodically detected. Here, the normal transport member 220n may refer to a transport member capable of transferring a substrate 20. The abnormal transport member 220u may refer to a transport member that is inoperable or needs to be stopped for a repair or an inspection.

More particularly, in the transport-member simultaneous operation mode, the integrated controller 800 may simultaneously operate the plurality of transport members 220 to transfer the substrate 20 between the plurality of track portions 100 and the exposure portion 300. For example, in the transport-member simultaneous operation mode, a first transport member 220a may transfer a first substrate between a first track portion 100a and an exposure portion 300, and a second transport member 220b may transfer a second substrate between a second track portion 100b and the exposure portion 300.

Also, the integrated controller 800 may periodically detect the states of the plurality of transport members 220 to periodically detect whether the plurality of transport members 220 are abnormal or not. For example, the plurality of track controllers 180 included in the plurality of transport members 220 may periodically check the states of the plurality of transport members 220 and provide the states of the plurality of transport members 220 to the integrated controller 800. However, the embodiment is not limited thereto, and the state of the plurality of transport members 220 may be periodically detected by any of various methods.

In an abnormal-transport-member determination step S32, it is determined whether an abnormal transport member 220u exists or not among the plurality of transport members 220. If the abnormal transport member 220u does not exist, the transport-member simultaneous operation step S30 may be performed.

If the abnormal transport member 220u exists, the transport-member simultaneous operation mode may be converted to a standby mode in a mode conversion step S34. In a standby step S36, the normal transport member 220n may move the abnormal transport member 220u to a standby region 250 to stand by and the remaining transport member or transport members (the normal transport member 220n or the normal transport members) may be operated. That is, in the standby mode, the abnormal transport member 220u is positioned in standby (i.e., taken out of operation) in the standby region 250 so that the abnormal transport member 220u does not interfere with a driving path of the normal transport member 220p. Then, the normal transport member 220p may access the plurality of buffer portions 230 corresponding to the plurality of track portions 100. In this state, the remaining transport member or transport members may transfer the substrate between the plurality of track portions 100 and the exposure portion 300. That is, the remaining transport member may perform a substrate transferring between one track portion that corresponded to the remaining transport member and the exposure portion, and between another track portion that corresponded to the abnormal transport member 220u and the exposure portion. For example, in the standby mode, one normal transport member 220n of the first and second transport members 220a and 220b may transfer a first substrate between the first track portion 100a and the exposure portion 300 and transfer a second substrate between the second track portion 100b and the exposure portion 300 together.

For example, in the standby mode, the integrated controller 800 may transmit a movement signal and a substrate transferring signal to a track controller 180 controlling the normal transport member 220n. The movement signal instructs the normal transport member 220n to move the abnormal transport member 220u to the standby region 250. The substrate transferring signal instructs the normal transport member 220n to transfer the substrate 20 of the plurality of track portions 100 after the movement of the abnormal transport member 220u. In some cases, a stop signal for stopping the abnormal transport member 220u may be transmitted to the track controller 180 controlling the abnormal transport member 220u. Accordingly, even when one of the plurality of transport members 220 is the abnormal transport member 220u, the substrate 20 may be transferred using the remaining normal transport member 220n or the remaining normal transport members.

On the other hand, if the standby region is not provided, substrate transferring between a normal track portion and an exposure portion may be stopped because an abnormal transport member interferes with a path of a normal transport member even when an abnormal track portion is not provided.

In an alarm step S38, the integrated controller 800 or the track controller 180 may generate a warning signal informing of the state of the abnormal transport member 220u and provide to a user, manager, etc., through the output portion of the integrated controller 800 or the track controller 180. Then, the user, manager, etc., may perform a repairing step S40 of repairing, inspecting, or replacing the abnormal transport member 220u.

After the repairing step S40, the transport-member simultaneous operation step S30 may be performed. Accordingly, a transport-member simultaneous operation mode may be performed. In the transport-member simultaneous operation mode, a plurality of transport members 220, which are normal transport members 220n, may be simultaneously operated and an existence of an abnormal transport member 220u may be periodically detected

According to the embodiment, the photolithography apparatus 10 is composed of an in-line-type, thereby reducing a delay time of a photolithography process and improving productivity of the photolithography process and a quality of a semiconductor device. For example, a critical dimension of a photoresist pattern 24f may be sensitively changed according to a post-exposure delay time. Accordingly, if the post-exposure delay time becomes longer, quality of a semiconductor device including a final pattern patterned using the photoresist pattern 24f may also be affected. In the embodiment, a change of a resist pattern and/or a critical dimension of a final pattern may be prevented or minimized by reducing the post-exposure delay time. Also, since a substrate 20 moves inside the photolithography apparatus 10 during a photolithography process, contamination of the substrate 20 may be prevented or minimized.

On the other hand, unlike the embodiment, in the photolithography apparatus in which a track portion and an exposure portion are separated, as a delay time of the photolithography process becomes longer, productivity of the photolithography process and a quality of a semiconductor device may deteriorate.

Also, in the embodiment, a stop loss due to stop of the track portion may be prevented by a plurality of track portions 100. That is, even when one or some track portions of the plurality of track portions 100 need to be stopped, when the remaining track portion or track portions are normal, the photolithography apparatus 10 may be operated using the normal track portion or track portions. For example, when one of the plurality of track portions 100 is in a full operation state, an exposure portion 300 may maintain a full operation state even if the other track portion stops. Alternatively, even when all of the plurality of track portions 100 are in a partial operation state, a full operation or a partial operation of the exposure portion 300 may be maintained because a supply of a substrate 20 by the plurality of track portions 100 are maintained. Therefore, the exposure portion 300 operates except when all of the plurality of track portions 100 are completely stopped, and thus, productivity may be improved by maximizing an operation rate of the exposure portion 300. On the other hand, in the prior art, one track portion is provided, and thus, an entire photolithography apparatus is stopped when the track portion is stopped due to a failure, resulting in a stop loss.

In addition, in the embodiment, a performance loss due to a performance degradation of the track portion may be prevented by a plurality of track portions 100. That is, even when one or some of the plurality of track portions 100 are stopped for maintenance or repairing, the photolithography apparatus 10 may be operated using the remaining track portion or track portions. Accordingly, since the maintenance or repairing of the track portion 100 may be performed in a timely manner, performance of the track portion 100 may be maximized and an operation rate of the exposure portion 300 may be highly maintained, thereby maintaining a homeostasis. Accordingly, even when being applied to a mass production, productivity and yield may be improved by stably maintaining a critical dimension, a defect, or the like. On the other hand, in the prior art, one track portion is provided. Thus, even when the performance of the track portion deteriorates or the maintenance or the repairing of the track portion is required, the photolithography apparatus is continuously operated so that the exposure portion does not stop. In this case, the productivity of the photolithography apparatus may be deteriorated due to the performance degradation of the track portion or the yield may be decreased due to the deteriorated quality of the semiconductor device, resulting in a performance loss.

Particularly, according to the embodiment, when the exposure portion 300 has a high numerical aperture (high NA), the stop loss and the performance loss of the photolithography apparatus 10 may be effectively prevented or minimized. This is because the exposure portion having the high numerical aperture is very expensive, and thus the stop loss or the performance loss may be serious. In addition, since the exposure portion having the high numerical aperture has a large installation space, a space may be further optimized by the plurality of track portions 100 as shown in the embodiment.

As described above, according to the embodiment, productivity of a photolithography process and a quality of a semiconductor device may be improved by minimizing a stop loss and a performance loss by a plurality of track portions 100. In addition, the productivity of the photolithography process may be further improved by preventing the stop loss caused by a transport member 220 by using a plurality of transport members 220 and a standby region 250 included in an interface portion 200.

A photolithography apparatus according to another embodiment will be described in detail with reference to FIG. 9 as follows. For parts identical or similar to those already described, detailed descriptions are omitted, and other parts will be described in detail.

FIG. 9 is a top plan view schematically showing a photolithography apparatus according to another embodiment.

Referring to FIG. 9, the photolithography apparatus 10 according to an embodiment may include an exposure portion 300, a plurality of track portions 100, and an interface portion 200, and further include an integrated controller 800.

In an embodiment, a plurality of track portions 100 may include three track portions (i.e., a first track portion 100a, a second track portion 100b, and a third track portion 100c). The description of the first track portion 100a and/or the second track portion 100b in the previous embodiment may be applied to the third track portion 100c.

That is, the third track portion 100c may include an index portion 110, a buffer portion 120, a process portion 130, a measurement portion 170, a track controller 180, and the like. The process portion 130 may include a process member 132 and a process transport member 134. The description for the first track portion 100a and/or the second track portion 100b in the previous embodiment may be applied to the index portion 110, the buffer portion 120, the process portion 130 including the process member 132 and the process transport member 134, the measurement portion 170, the track controller 180, or the like of the third track portion 100c.

In an embodiment, the first to third track portion 100a, 100b, and 100c included in the plurality of track portions 100 may have the same or similar structure, but the embodiment is not limited thereto. Therefore, there may be a difference in structure, type, etc., of at least one of the first to third track portions 100a, 100b, and 100c included in the plurality of track portions 100 according to the embodiment. For example, the first to third track portions 100a, 100b, and 100c may have differences in arrangement, a number of the process members 132. Other numerous variations are possible.

A plurality of track portions 100 (e.g., first to third track portion 100a, 100b, and 100c) may be spaced apart from each other in the second direction (the Y-axis direction of the drawing). However, the embodiment is not limited thereto, and at least some of the plurality of track portions 100 may be positioned adjacent to each other. For example, in the second direction, a virtual center line of the plurality of track portions 100 may coincide with a virtual center line of the exposure portion 300 or may be positioned apart from the virtual center line of the exposure portion 300.

The interface portion 200 may include a common rail 210 and a plurality of transport members 220, and may further include a buffer portion 230, a preprocessing portion 240, and a standby region 250. In the interface portion 200, a plurality of processing portions including the buffer portion 230 and the preprocessing portion 240 may be provided in correspondence with the plurality of track portions 100 (e.g., to have one-to-one correspondence). For example, the processing portion may include a first processing portion corresponding to the first track portion 100a, a second processing portion corresponding to the second track portion 100b, and a third processing portion corresponding to the third track portion 100c.

In an embodiment, a plurality of transport members 220 may include a first transport member 220a and a second transport member 220b. As such, a number of the plurality of transport members 220 may be different from a number of the plurality of track portions 100. The plurality of transport members 220 consist of two transport members of the first transport member 220a and the second transport member 220b, which may smoothly transfer the substrate between the plurality of track portions 100 and exposure portion 300 and then easily move the abnormal transport member 220u to the standby region 250.

However, the embodiment is not limited to this. In the embodiment with reference to FIG. 1, the plurality of transport members 220 may correspond to the plurality of track portions 100 (e.g., to have one-to-one correspondence). For example, a plurality of transport members may include a first transport member, a second transport member, and a third transport member respectively corresponding to the first track portion 100a, the second track portion 100b, and the third track portion 100c. In addition, numerous variations are possible, such as a number of plurality of transport members 220 being less than or greater than the number of plurality of track portions 100.

FIG. 9 illustrates that the plurality of track portions 100 includes three track portions, but the embodiment is not limited thereto. The plurality of track portions 100 may include four or more track portions.

FIG. 10 is a top plan view schematically showing a track portion included in a photolithography apparatus according to yet another embodiment.

Referring to FIG. 10, in an embodiment, a measurement portion 170 may be provided at a process portion 130. In the embodiment, since a plurality of track portions 100 are provided, an extra space may be formed in the process portion 130 of each track portion, so that the measurement portion 170 may be positioned inside the process portion 130.

For example, a separate measurement space 172 in which the measurement portion 170 is positioned may be provided in a process member 132 of a process portion 130, and the measurement portion 170 may be positioned in the measurement space 172. For example, the measurement space 172 may positioned at a position of a movement path of a substrate after a developing portion 150, a post-exposure bake portion 164, and a hard bake portion 166. For example, the measurement space 172 is provided in the first process member 132a and may be positioned adjacent to the buffer portion 120. According to this, a path for transporting a substrate having a photoresist pattern in a final state to the measurement space may be reduced. However, the embodiment is not limited thereto. As another example, the measurement space 172 may be provided in a second process member 132b or in a position not adjacent to a buffer portion 120. In addition, a position and a structure of the measurement space 172 and/or the measurement portion 170 may be modified in various ways.

While this disclosure has been described in connection with what is presently considered to be practical embodiments, it is to be understood that the invention is not limited to the disclosed embodiments. On the contrary, it is intended to cover various modifications and equivalent arrangements included within the scope of the appended claims

What is claimed is:

1. A photolithography apparatus comprising:
an exposure portion configured to perform an exposure process on a substrate;
a plurality of track portions, each of the plurality of track portions configured to perform a coating process and a developing process on the substrate; and
an interface portion connecting the exposure portion and the plurality of track portions, wherein the interface portion is configured to transfer the substrate between the exposure portion and the plurality of track portions.

2. The photolithography apparatus of claim 1, wherein:
the plurality of track portions are positioned at a first side of the interface portion in a first direction and spaced apart from each other in a second direction that is transverse to the first direction, and
the exposure portion is positioned at an opposite second side of the interface portion in the first direction and includes one exposure portion.

3. The photolithography apparatus of claim 1, wherein:
the interface portion comprises an elongate common rail and a plurality of transport members configured to move on the common rail.

4. The photolithography apparatus of claim 3, wherein:
each of the plurality of transport members is operatively associated with a respective one of the plurality of track portions.

5. The photolithography apparatus of claim 3, wherein:
at least one of the plurality of transport members comprises a bumper portion positioned adjacent to another one of the plurality of transport members.

6. The photolithography apparatus of claim 3, wherein:
the elongate common rail extends from a first side of the interface portion to an opposite second side of the interface portion, and
the interface portion comprises a standby region adjacent an end portion of the common rail, and wherein at least one of the plurality of transport members is configured to be positioned in the standby region.

7. The photolithography apparatus of claim 6, wherein:
the interface portion further comprises a door member that connects the standby region to an external environment or separates the standby region from the external environment on at least one side of the standby region.

8. The photolithography apparatus of claim 6, wherein:
the interface portion further comprises a separation member that separates the standby region from an internal region of the interface portion.

9. The photolithography apparatus of claim 8, wherein:
the separation member comprises a shutter member positioned between the standby region and the internal region or an air curtain member configured to provide air between the standby region and the internal region.

10. The photolithography apparatus of claim 3, wherein:
the interface portion comprises a plurality of processing portions, each of the plurality of processing portions corresponding to a respective one of the plurality of track portions, and wherein each of the plurality of processing portions comprises a buffer portion on which the substrate is positioned.

11. The photolithography apparatus of claim 10, wherein:
the processing portion comprises at least one of a cleaning portion and an edge exposure portion positioned on at least one side of the buffer portion.

12. The photolithography apparatus of claim 10, wherein:
each one of the plurality of processing portions is positioned adjacent to a respective one of the plurality of track portions, and
the common rail and the plurality of transport members are positioned adjacent to the exposure portion.

13. The photolithography apparatus of claim 1, wherein:
the track portion comprises a measurement portion configured to measure a critical dimension of a photoresist pattern provided on the substrate.

14. The photolithography apparatus of claim 1, further comprising:
an integrated controller configured to control the exposure portion and the plurality of track portions.

15. An operation method of a photolithography apparatus, the method comprising:
forming a photoresist layer on each of a plurality of substrates, wherein each of the plurality of substrates is located within a respective one of a plurality of track portions;
transferring the plurality of substrates to an exposure portion and performing an exposure process on the plurality of substrates in the exposure portion to form an exposed photoresist layer on each of the plurality of substrates; and
transferring the plurality of substrates to the plurality of track portions and performing a developing process on the exposed photoresist layer on each of the plurality of substrates in the plurality of track portions.

16. The operation method of the photolithography apparatus of claim 15, wherein:
when each of the plurality of track portions is operating normally, either in a fully operational state or a partial operational state, the plurality of track portions are operated simultaneously.

17. The operation method of the photolithography apparatus of claim 15, wherein:
when one of the plurality of track portions is operating abnormally, the one of the plurality of track portions that is operating abnormally is stopped and remaining ones of the plurality of track portions are selectively operated.

18. The operation method of the photolithography apparatus of claim 15, further comprising:
after performing the developing process,
measuring a critical dimension of a photoresist pattern provided on each of the plurality of substrates; and
correcting an exposure condition of the exposure portion in response to the critical dimension of the photoresist pattern.

19. An operation method of a photolithography apparatus including an exposure portion, a plurality of track portions, and an interface portion, the method comprising:
periodically detecting whether any of the plurality of track portions are operating abnormally while operating the plurality of track portions simultaneously either in a fully operational state or a partial operational state; and
in response to detecting that one of the plurality of track portions is operating abnormally, stopping the one of the plurality of track portions that is operating abnormally and selectively operating remaining ones of the plurality of track portions.

20. The operation method of the photolithography apparatus of claim 19, wherein:
the interface portion comprises a plurality of transport members, each of the plurality of transport members configured to transfer a substrate between the plurality of track portions and the exposure portion, and
when one of the plurality of transport members is detected as operating abnormally, another one of the plurality of transport members is configured to move the one of the plurality of transport members that is operating abnormally to a standby region and to simultaneously perform a substrate transfer between one track portion that corresponded to the another one of the plurality of transport members and the exposure portion and between another track portion that corresponded to the one of the plurality of transport members that is operating abnormally and the exposure portion.
